(19) United States
(12) Patent Application Publication
(10) Pub. No.: US 2026/0171143 A1
(43) Pub. Date: Jun. 18, 2026

(54) SEMICONDUCTOR STORAGE DEVICE AND MANUFACTURING METHOD THEREOF

(71) Applicant: Kioxia Corporation, Tokyo (JP)

(72) Inventor: Mamoru ISHIZAKA, Hiratsuka (JP)

(73) Assignee: Kioxia Corporation, Tokyo (JP)

(21) Appl. No.: 19/286,371

(22) Filed: Jul. 31, 2025

(30) Foreign Application Priority Data
Dec. 12, 2024 (JP) 2024-217681

(51) Int. Cl. G11C 11/4096

(52) U.S. Cl. CPC G11C 11/4096

(57) ABSTRACT

First and second wires are connected to cells arranged in a first and second directions. A first driving line is common to the first wires arranged in a third direction. A first transistor is connected between the first wire and the first driving line. A fourth wire is connected to gates of the first transistors arranged in the second direction. A second driving line is provided for the first wires arranged in the second direction. A second transistor is connected between the first wire and the second driving line. A fifth wire is connected to gates of the second transistors arranged in the second direction in common. A driver circuit applies a first voltage to the fifth wire corresponding to one of the first wires that is non-selected in a selected bank and applies a second voltage smaller than the first voltage to the fifth wires in a non-selected bank.

### CROSS REFERENCE TO RELATED APPLICATIONS

This application is based upon and claims the benefit of priority from the prior Japanese Patent Application No. 2024-217681, filed on December 12, 2024, the entire contents of which are incorporated herein by reference.

### FIELD

The embodiments of the present invention relate to a semiconductor storage device and manufacturing method thereof.

### BACKGROUND

Semiconductor storage devices including memory cells arranged three-dimensionally, such as a DRAM (Dynamic Random Access Memory), are being developed. In a three-dimensional memory portion, switches are provided at both ends of word lines, respectively, and a voltage of each word line may be made a selected voltage or a non-selected voltage by controlling the switches.

### BRIEF DESCRIPTION OF THE DRAWINGS

FIG. 1A is a block diagram illustrating a configuration example of a semiconductor storage device according to a first embodiment;

FIG. 1B is a block diagram illustrating a configuration example of a bank;

FIG. 1C is a block diagram illustrating a configuration example of a cell array;

FIG. 2 is a diagram illustrating a configuration example of a cell array;

FIG. 3 is a circuit diagram illustrating a configuration example of a memory cell;

FIG. 4 is a block diagram illustrating a configuration example of a row decoder, a main word-line driver, and a bank according to the first embodiment;

FIG. 5 is a timing chart illustrating an operation example of the semiconductor storage device according to the first embodiment;

FIG. 6 is a block diagram illustrating a configuration example of a semiconductor storage device according to a second embodiment; and

FIG. 7 is a timing chart illustrating an operation example of the semiconductor storage device according to the second embodiment.

### DETAILED DESCRIPTION

In general, according to the embodiment, a semiconductor storage device includes a memory portion including a plurality of banks each of which includes a plurality of memory cells. Each of the banks is selectively accessed in a data read operation or a data write operation. A plurality of first wires are respectively connected to the memory cells arranged in a first direction in common in the memory portion. A plurality of second wires are respectively connected to the memory cells arranged in a second direction crossing the first direction in common in the memory portion. A plurality of third wires are respectively provided for the second wires arranged in a third direction crossing the first and second directions in common. A plurality of first driving lines are respectively connected to the first wires arranged in the third direction in common. A plurality of first transistors in each of which one of a source and a drain is connected to corresponding one of the first wires, and another is connected to corresponding one of the first driving lines. A plurality of fourth wires are respectively connected to gates of the first transistors arranged in the second direction in common. A plurality of second driving lines are respectively provided for the first wires arranged in the second direction in common. A plurality of second transistors in each of which one of a source and a drain is connected to corresponding one of the first wires and another is connected to corresponding one of the second driving lines. A plurality of fifth wires are respectively connected to gates of the second transistors arranged in the second direction in common. A driver circuit drives voltages of the fourth and fifth wires. The driver circuit applies a first voltage to one of the fifth wires corresponding to non-selected one of the first wires in a first bank selected in the banks and applies a second voltage having an absolute value smaller than an absolute value of the first voltage to the fifth wires in a second bank that is non-selected.

Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

### (First Embodiment)

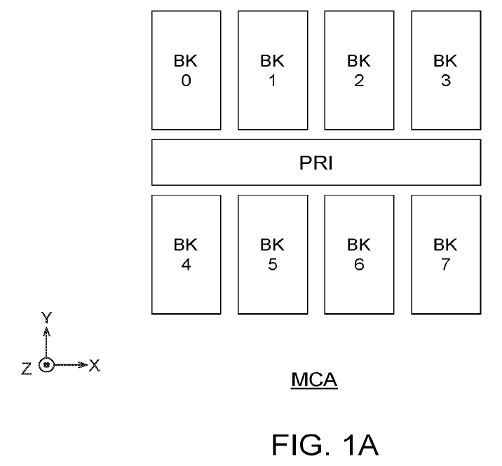

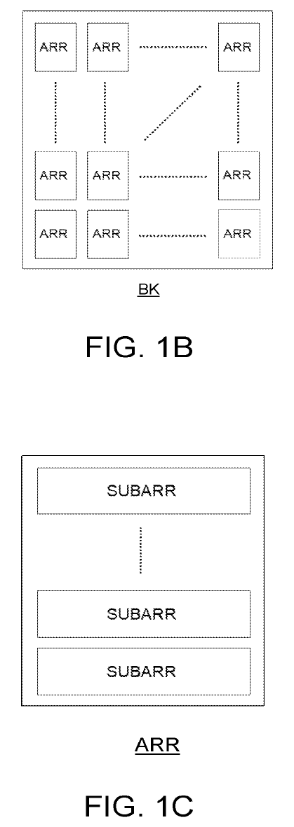

FIG. 1A is a block diagram illustrating a configuration example of a semiconductor storage device 1 according to a first embodiment. The semiconductor storage device 1 according to the present embodiment is a DRAM including a memory cell array MCA in which memory cells MC are arranged two-dimensionally (in a planar manner) or three-dimensionally (in a spatial manner), for example. In the present embodiment, the three-dimensional memory cell array MCA is described. Each memory cell MC is used as a memory cell for storing 1-bit data or multi-bit data therein.

The memory cell array MCA is divided into a plurality of banks BK0 to BK7. Each of the banks BK0 to BK7 is a unit of the memory cells MC selectively accessed in a data read operation or a data write operation. The number of banks BK included in the memory cell array MCA is not limited.

A peripheral circuit PRI is a logic circuit controlling access to the banks BK0 to BK7 and is configured by a CMOS (Complementary Metal Oxide Semiconductor) circuit. The memory cell array MCA and the peripheral circuit PRI can be configured as a single semiconductor chip. Alternatively, an array chip including the memory cell array MCA and a CMOS chip including the peripheral circuit PRI are manufactured separately from each other and are then bonded together to form a one chip.

FIG. 1B is a block diagram illustrating a configuration example of each bank BK. Each bank BK is divided into a plurality of cell arrays ARR. The number of cell arrays ARR included in the bank BK is not limited.

FIG. 1C is a block diagram illustrating a configuration example of each cell array ARR. Each cell array ARR is divided into a plurality of sub arrays SUBARR. The number of sub arrays SUBARR included in the cell array ARR is not limited.

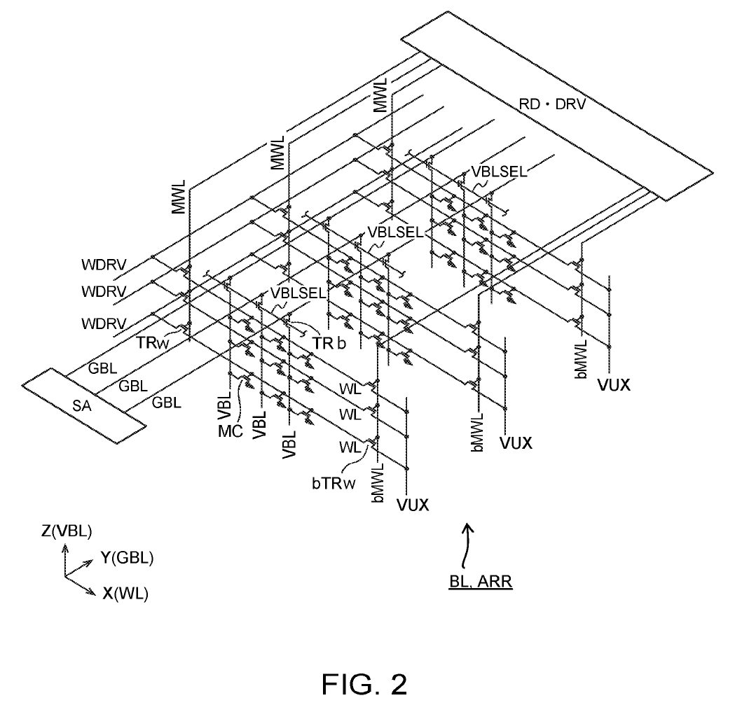

FIG. 2 is a diagram illustrating a configuration example of the cell array ARR in one bank BK. According to the present embodiment, the memory cells MC are arranged three-dimensionally, for example, in the X-, Y-, and Z-directions to form the three-dimensional memory cell array MCA (the banks BK and the cell arrays ARR). The X-, Y-, and Z-directions are directions crossing one another and, for example, are orthogonal coordinate axes.

The semiconductor storage device 1 according to the present embodiment includes the memory cell array MCA, a plurality of word lines WL, a plurality of bit lines VBL, a plurality of main word lines MWL and bMWL, a plurality of global bit lines GBL, a plurality of bit selection lines VBLSEL, word driving line WDRV and VUX, a row decoder RD, a main word-line driver DRV, and a sense amplifier circuit SA.

The word lines WL as first wires extend in the X-direction in the bank BK or the cell array ARR and are each connected to the memory cells MC arranged in the X-direction in common. The word lines WL are arranged in the Z- and Y-direction in the memory cell array MCA. One ends of the word lines WL are connected to the word driving lines WDRV via a plurality of transistors TRw, respectively. The other ends of the word lines WL are connected to the word driving lines VUX via a plurality of transistors bTRw, respectively.

The bit lines VBL as second wires extend in the Z-direction in the bank BK or the cell array ARR and are each connected to the memory cells MC arranged in the Z-direction in common. The bit lines VBL are arranged in the X- and Y-direction in the bank BK or the cell array ARR. One ends of the bit lines VBL are each connected to any of the global bit lines GBL via corresponding one of transistors TRb.

The global bit lines GBL as third wires extend in the Y-direction and are each provided for the bit lines VBL arranged in the Y-direction in common.

The transistors TRb are connected between the bit lines VBL and the global bit lines GBL, respectively. One of the source and the drain of each transistor TRb is connected to the corresponding bit line VBL, and the other is connected to the corresponding global bit line GBL. The gate of the transistor TRb is connected to the corresponding bit selection line VBLSEL.

The bit selection lines VBLSEL are each connected to the gates of the transistors TRb arranged in the X-direction in common. Each bit selection line VBLSEL can connect the bit lines VBL arranged in the X-direction to the global bit lines GBL respectively corresponding thereto. Accordingly, the bit lines VBL can be connected to the sense amplifier circuit SA via the global bit lines GBL respectively corresponding thereto.

The word driving lines WDRV as first driving lines extend in the Y-direction and are each provided for the word lines WL arranged in the Y-direction in common. In a data read operation or a data write operation, each word driving line WDRV transmits a voltage (e.g., +1.5 V) applied to a selected word line WL in a selected bank BK (first bank) selectively accessed or a voltage (e.g., -1.0 V) applied to a non-selected word line WL in the selected bank BK.

In each of the transistors TRw as first transistors, one of the source and the drain is connected to the corresponding word line WL, and the other is connected to the corresponding word driving line WDRV.

The main word lines MWL as fourth wires are each connected to the gates of the transistors TRw arranged in the Z-direction in common. The main word lines MWL are connected to the row decoder RD and the main word-line driver DRV. Voltages of the main word lines MWL are selectively driven by the row decoder RD and the main word-line driver DRV. Voltages of the word driving lines WDRV and VUX each transmitting a voltage to the corresponding word line WL are driven by another word-line driver (not illustrated).

The word driving lines VUX as second driving lines extend in the Z-direction and are each provided for the word lines WL arranged in the Z-direction in common. In a data read operation or a data write operation, the word driving lines VUX transmit a voltage (e.g., -1.0 V) applied to the non-selected word lines WL in the selected bank BK and a non-selected bank BK.

In each of the transistors bTRw as second transistors, one of the source and the drain is connected to the corresponding word line WL, and the other is connected to the corresponding word driving line VUX.

The main word lines bMWL as fifth wires are each connected to the gates of the transistors bTRw arranged in the Z-direction in common. The main word lines bMWL are connected to the row decoder RD and the main word-line driver DRV. Voltages of the main word lines bMWL are selectively driven by the row decoder RD and the main word-line driver DRV.

The row decoder RD is connected to the main word lines MWL and bMWL and selectively controls the voltages of the main word lines MWL and bMWL in accordance with a bank address and a word-line address. The main word-line driver DRV selectively applies voltages to the main word lines MWL and bMWL based on the bank address and the word-line address from the row decoder RD. For example, the main word-line driver DRV applies a first voltage (e.g., 2 V) to the main word line MWL corresponding to the selected word line WL selected by the row decoder RD to make the transistors TRw connected to that main word line MWL conducting (on). The main word-line driver DRV applies a third voltage (e.g., -1.5 V) to the main word line MWL corresponding to the non-selected word line WL to make the transistors TRw connected to that main word line MWL non-conducting (off).

Further, the main word-line driver DRV applies the third voltage (e.g., -1.5 V) to the main word line bMWL corresponding to the selected word line WL to turn the transistors bTRw off. The main word-line driver DRV applies the first voltage (e.g., 2 V) to the main word line bMWL corresponding to the non-selected word line WL in the selected bank BK to make the transistor bTRw conducting (on). Furthermore, the main word-line driver DRV according to the present embodiment applies a second voltage (e.g., 0.5 V) to the main word line bMWL corresponding to all the word lines WL (non-selected word lines) in the non-selected bank BK (second bank).

The absolute value of the second voltage applied to the main word lines bMWL in the non-selected bank BK is smaller than the absolute value of the first voltage applied to the main word line bMWL corresponding to the non-selected word line WL in the selected bank BK. In a case where the number of the banks BK in the memory cell array MCA is large, a period in which a bank is ready as the non-selected bank BK is much longer than a period in which that bank is accessed as the selected bank BK in a read operation or a write operation. Therefore, by making the absolute value of the second voltage applied to the main word lines bMWL in the non-selected bank BK smaller than the absolute value of the first voltage, deterioration of the transistor bTRw due to PBTI (Positive Bias Temperature Instability) or NBTI (Negative Bias Temperature Instability) can be reduced.

For example, it is assumed that the voltage of the main word lines bMWL in the non-selected bank BK is made equal to the first voltage (e.g., 2 V) applied to the main word line bMWL corresponding to the non-selected word line WL in the selected bank BK. In this case, the transistor bTRw in the non-selected bank BK in the standby state continues to be on at the first voltage that is relatively high for a long time. Accordingly, the transistor bTRw can easily deteriorate due to PBTI.

Meanwhile, according to the present embodiment, the transistor bTRw in the non-selected bank BK in the standby state continues to be on at the second voltage (e.g., 0.5 V) having the absolute value smaller than the absolute value of the first voltage. Accordingly, the transistor bTRw is less likely to deteriorate. The second voltage may be less than 0.5 V.

The transistors TRw, bTRw, and TRb may, for example, be either n-type or p-type MOSFETs (Metal Oxide Semiconductor Field Effect Transistors). Herein, the description is provided assuming that the transistors TRw, bTRw, and TRb are n-type MOSFETs.

The sense amplifier circuit SA detects data stored in the selected memory cell MC connected to the selected word line WL via the bit line VBL in a read operation. Alternatively, the sense amplifier circuit SA applies a write voltage to the selected memory cell MC connected to the selected word line WL to write data thereto in a write operation.

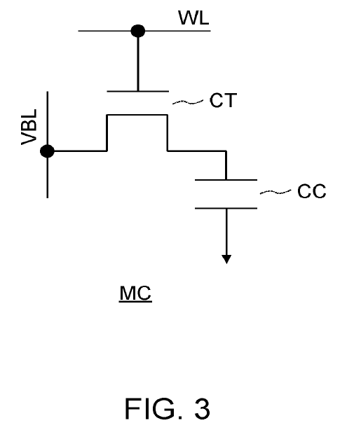

FIG. 3 is a circuit diagram illustrating a configuration example of each memory cell MC. Each memory cell MC includes one cell transistor CT and one cell capacitor CC.

One of the source and the drain of the cell transistor CT is connected to any of the bit lines VBL, and the other is connected to one end of the cell capacitor CC. The gate of the cell transistor CT is connected to any of the word lines WL.

The cell capacitor CC is connected between the cell transistor CT and a reference voltage source (e.g., ground).

Each of the memory cells MC has mutually the same configuration.

Each memory cell MC can store logical data therein by accumulating electric charges in the cell capacitor CC or discharging electric charges from the cell capacitor CC via the cell transistor CT.

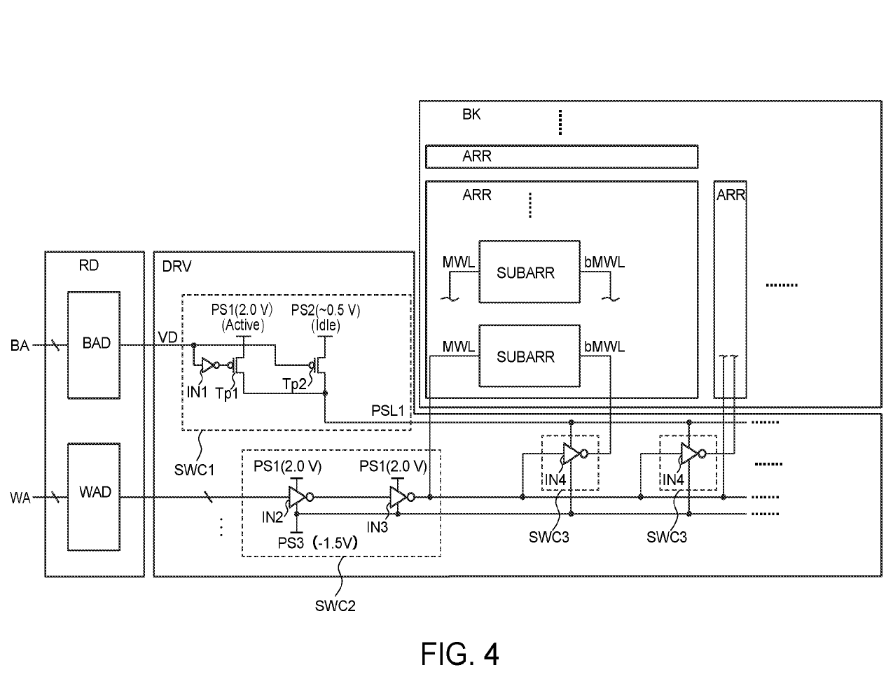

FIG. 4 is a block diagram illustrating a configuration example of the row decoder RD, the main word-line driver DRV, and the bank BK according to the first embodiment.

Each bank BK includes the cell arrays ARR each of which includes the sub arrays SUBARR. One sub array SUBARR is configured by the memory cells MC corresponding to one pair of the main word line MWL and the main word line bMWL. For example, the sub array SUBARR is configured by the memory cells MC arranged two-dimensionally in the X-Z plane in FIG. 2. The bank BK, the cell array ARR, and the sub array SUBARR are a concept of convenient divisions of the memory cell array MCA, and the unit of each of them may be changed in a desired manner.

The row decoder RD includes a bank address decoder BAD and a word-line address decoder WAD. The row decoder RD is provided for each memory cell array MCA. The bank address decoder BAD decodes the bank address BA selecting the bank BK as a target of reading or writing in the memory cell array MCA. The word-line address decoder WAD decodes the word-line address WA selecting the word line WL as a target of reading or writing in the selected bank BK.

The main word-line driver DRV connects any of power terminals PS1 to PS3 to the main word line MWL or bMWL based on the bank address BA and the word-line address WA thus decoded. The main word-line driver DRV accordingly applies a voltage of any of the power terminals PS1 to PS3 to the main word line MWL or bMWL.

The power terminal PS1 is a power terminal supplying a high-level voltage (e.g., 2 V) as the first voltage which is a voltage turning the transistors TRw and bTRw in FIG. 2 on. That is, the power terminal PS1 supplies the first voltage electrically connecting the word driving line WDRV or VUX to the corresponding word line WL to the main word lines MWL and bMWL.

The power terminal PS2 is a power terminal supplying a medium-level voltage (e.g., 0.5 V) as the second voltage. The second voltage of the power terminal PS2 is lower than the first voltage of the power terminal PS1 and is higher than the third voltage of the power terminal PS3. Although the second voltage is a voltage turning the transistor bTRw in FIG. 2 on, it is lower than the first voltage. Therefore, the transistor bTRw receiving the second voltage at its gate is turned on with relatively high resistance. That is, while the second voltage electrically connects the word driving line VUX to the corresponding word line WL, the second voltage makes the resistance of the transistor bTRw between the word driving line VUX and the corresponding word line WL higher than in a case where the first voltage is supplied.

The power terminal PS3 is a power terminal supplying a low-level voltage (e.g., -1.5 V) as the third voltage which is a voltage turning the transistors TRw and bTRw in FIG. 2 off. That is, the power terminal PS3 supplies the third voltage electrically disconnecting the word driving line WDRV or VUX from the corresponding word line WL to the main word lines MWL and bMWL.

The main word-line driver DRV includes switching circuits SWC1 to SWC3.

The switching circuit SWC1 is connected between the bank address decoder BAD and the switching circuit SWC3. The switching circuit SWC1 connects either one of the power terminals PS1 and PS2 to the main word line bMWL via the switching circuit SWC3 based on the bank address BA specifying the selected bank BK as a target of reading or writing. Since the switching circuit SWC1 operates based on the bank address BA, it is provided for each of the banks BK.

The switching circuit SWC1 includes a transistor Tp1 as a first switching element, a transistor Tp2 as a second switching element, an inverter circuit IN1, and a power line PSL1.

One of the source and the drain of the transistor Tp1 is connected to the power line PS1, and the other is connected to the power line PSL1. The gate of the transistor Tp1 receives a first signal according to the bank address BA. The first signal is a signal obtained by inverting a signal VD corresponding to the bank address BA by the inverter circuit IN1, for example. The transistor Tp1 is a p-MOSFET, for example. When the bank address BA is at high level, for example, the transistor Tp1 is on and connects the power terminal PS1 to the power line PSL1 to supply the first voltage (e.g., 2 V) to the power line PSL1.

One of the source and the drain of the transistor Tp2 is connected to the power line PS2, and the other is connected to the power line PSL1. The gate of the transistor Tp2 receives a second signal, which is a reverse logic of the first signal, in accordance with the bank address BA. The second signal is a non-inverted signal of the signal VD corresponding to the bank address BA, for example. The transistor Tp2 is a p-MOSFET, for example. When the bank address BA is at low level, for example, the transistor Tp2 is on and connects the power terminal PS2 to the power line PSL1 to supply the second voltage (e.g., 0.5 V) to the power line PSL1.

The power line PSL1 is provided for the sub arrays SUBARR of one bank BK in common and is connected to each of the main word line bMWL via the switching circuit SWC3. Accordingly, in a case where the switching circuit SWC3 connects the power line PSL1 to its corresponding main word line bMWL, the other end of the transistor Tp1 or Tp2 is electrically connected to that main word line bMWL. In this case, the first or second voltage from the power terminal PS1 or PS2 can be applied to that main word line bMWL.

For example, in the selected bank BK, the transistor Tp1 connects the power terminal PS1 to the main word line bMWL corresponding to the non-selected word line WL. The first voltage (e.g., 2 V) from the power terminal PS1 can be applied to the main word lines bMWL in the non-selected sub array SUBARR in this manner. In the non-selected bank BK, the transistor Tp2 connects the power terminal PS2 to the main word lines bMWL in the non-selected bank BK. The second voltage (e.g., 0.5 V) from the power terminal PS2 can be applied to the main word lines bMWL in the non-selected bank BK in this way.

As described above, the switching circuit SWC1 can switch the power terminals for each bank BK based on the bank address BA to supply either one of the first voltage from the power terminal PS1 and the second voltage from the power terminal PS2 to the main word line bMWL.

The switching circuit SWC2 is connected between the word-line address decoder WAD and the switching circuit SWC3. The switching circuit SWC2 connects either one of the power terminals PS1 and PS3 to each main word line MWL based on the word-line address WA specifying the selected word line WL as a target of reading or writing. Further, the switching circuit SWC2 connects either one of the power terminals PS1 and PS3 to each main word line bMWL via the switching circuit SWC3 based on the word-line address WA. Since the switching circuit SWC2 operates based on the word-line address WA, it is provided for each of the main word lines MWL.

The switching circuit SWC2 includes inverter circuits IN2 and IN3. The inverter circuit IN2 is connected to the power terminals PS1 and PS3, and outputs a voltage from either PS1 or PS3 based on the word-line address WA. The inverter circuit IN3 is connected to the power terminals PS1 and PS3, and outputs a voltage from either PS1 or PS3 based on the output of inverter circuit IN2. Since the inverter circuits IN2 and IN3 are connected in series to each other, the switching circuit SWC2 supplies the voltage according to the logic of the word-line address WA to the main word line MWL or the switching circuit SWC3.

For example, in the selected bank BK, the switching circuit SWC2 connects the power terminal PS1 to the main word line MWL corresponding to the word line WL selected in accordance with the word-line address WA and applies the first voltage (e.g., 2 V) thereto. Further, in the selected bank BK, the switching circuit SWC2 connects the power terminal PS3 to the main word line MWL corresponding to the non-selected word line WL in accordance with the word-line address WA and applies the third voltage (e.g., -1.5 V) thereto.

Similarly, in the selected bank BK, the switching circuit SWC2 connects the power terminal PS3 to the switching circuit SWC3 corresponding to the selected word line WL. The third voltage (e.g., -1.5 V) is applied to the main word line bMWL corresponding to the selected word line WL. Furthermore, in the selected bank BK, the switching circuit SWC2 connects the power terminal PS1 to the switching circuit SWC3 corresponding to the non-selected word line WL. The first voltage (e.g., 2 V) is applied to the main word line bMWL corresponding to the non-selected word line WL.

As described above, the switching circuit SWC2 can switch the power terminals for each word line WL based on the word-line address WA to supply either one of the first voltage from the power terminal PS1 and the third voltage from the power terminal PS3 to the main word line MWL and the switching circuit SWC3. While the switching circuit SWC2 is provided to correspond to each sub array SUBARR in one cell array ARR, the switching circuit SWC2 is shared by the sub arrays SUBARR included in the different cell arrays ARR adjacent to each other in the lateral direction in FIG. 4 .

Although the switching circuit SWC2 includes the two inverter circuits IN2 and IN3 connected in series, it may be configured by an even number of inverter circuits connected in series, the even number being four or more.

The switching circuit SWC3 is connected between the switching circuit SWC2 and each main word line bMWL. The switching circuit SWC3 connects either one of the power terminal PS1 or PS2 from the switching circuit SWC1 and the power terminal PS3 to each of the main word lines bMWL based on the output of the switching circuit SWC2. The switching circuit SWC3 is configured by an inverter circuit IN4. The switching circuit SWC3 may be configured by an odd number of inverter circuits connected in series, the odd number being three or more.

Since the output of the switching circuit SWC2 is driven based on the word-line address WA, the switching circuit SWC3 consequently applies either one of the power terminal PS1 or PS2 and the power terminal PS3 to the main word line bMWL based on the word-line address WA. Therefore, the input of the switching circuit SWC3 may be connected to the output of the word-line address decoder WAD, and a signal according to the word-line address WA may be input to the switching circuit SWC3. Since the switching circuit SWC3 operates based on the word-line address WA, the switching circuit SWC3 is provided to correspond to each of the main word lines bMWL. Since a pair of the main word line MWL and the main word line bMWL is provided for each sub array SUBARR, it can be said that the switching circuit SWC3 is provided for each sub array SUBARR.

For example, in a case where the output of the switching circuit SWC2 is the first voltage of the power terminal PS1, the word-line address WA specifies the selected word line WL. The switching circuit SWC3 thus connects the power terminal PS3 to the main word line bMWL corresponding to the selected word line WL to apply the third voltage (e.g., -1.5 V) thereto. Accordingly, the word driving line VUX is disconnected from the word lines WL of the selected sub array SUBARR.

In a case where the output of the switching circuit SWC2 is the third voltage of the power terminal PS3, the word-line address WA represents the non-selected word line WL. The switching circuit SWC3 thus connects the power line PSL1 to the main word line bMWL corresponding to the non-selected word line WL to apply the first or second voltage (e.g., 2 V or 0.5 V) of the power terminal PS1 or PS2 thereto. In this case, in the selected bank BK including the selected word line WL, the power line PSL1 transmits the first voltage of the power terminal PS1. The switching circuit SWC3 thus applies the first voltage of the power terminal PS1 to the main word line bMWL. The selected bank BK includes the selected sub array SUBARR connected to the selected main word lines MWL and bMWL (the sub arrays SUBARR adjacent to each other in the lateral direction in FIG. 4 and respectively included in the different cell arrays ARR) and the sub arrays SUBARR connected to the remaining non-selected main word lines MWL and bMWL.

In the selected bank BK, the selected word line WL may be adjacent to the non-selected word line WL. In this case, the voltage of the non-selected word line WL may be affected by the selected word line WL due to capacitive coupling between the word lines WL adjacent to each other (coupling noise). In the present embodiment, the main word line bMWL applies the first voltage of the power terminal PS1 to the transistor bTRw to place the transistor bTRw in the low-resistance on state. The non-selected word line WL is thus connected to the word driving line VUX with low resistance. Accordingly, the non-selected word line WL is maintained at the voltage (e.g., -1 V) of the word driving line VUX, so that the coupling noise described above can be reduced.

Further, it is preferable that the non-selected word line WL sharing the word driving line WDRV with the selected word line WL is connected to the word driving line VUX with low resistance so as to prevent a change in its voltage by current leakage from the word driving line WDRV.

Meanwhile, in the non-selected bank BK not including the selected word line WL, the power line PSL1 transmits the second voltage of the power terminal PS2. The switching circuit SWC3 thus applies the second voltage of the power terminal PS2 to the main word line bMWL. Accordingly, in the non-selected bank BK in the standby state, the switching circuit SWC3 applies the second voltage of the power terminal PS2 to the main word line bMWL. As a result, deterioration of the transistor bTRw can be reduced.

In this case, although the word driving line VUX and the word line WL are electrically connected to each other, they are connected with relatively high resistance. However, in the non-selected bank BK, all the word lines WL are non-selected word lines. Accordingly, it is not necessary to consider coupling noise, and thus there is no problem even if the resistance between the word driving line VUX and the word line WL is high to some extent.

Next, operations of the semiconductor storage device according to the present embodiment are described.

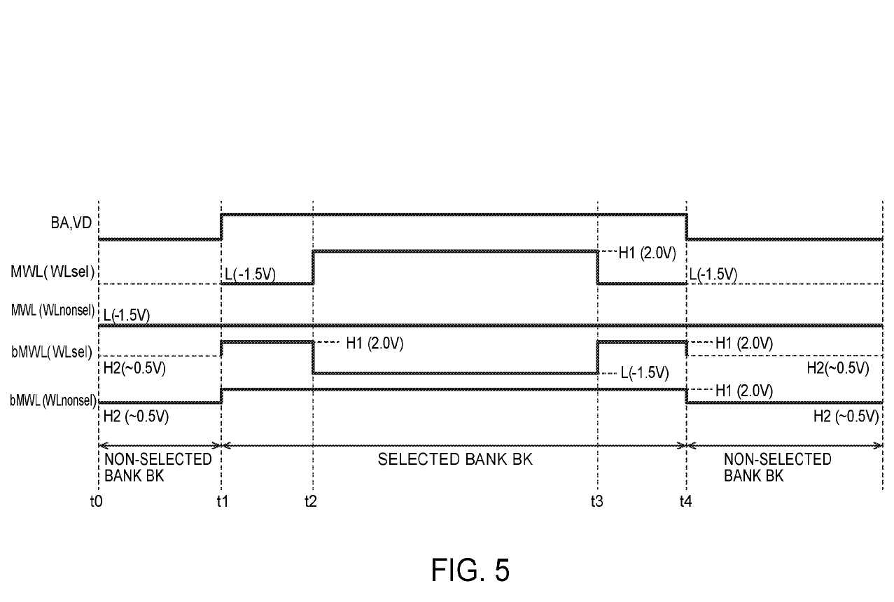

FIG. 5 is a timing chart illustrating an operation example of the semiconductor storage device according to the first embodiment. Additionally, MWL(WLsel) represents the voltage of the main word line MWL corresponding to the selected word line WL. MWL(WLnonsel) represents the voltage of the main word line MWL corresponding to the non-selected word line WL. Similarly, bMWL(WLsel) represents the voltage of the main word line bMWL corresponding to the selected word line WL, and bMWL(WLnonsel) represents the voltage of the main word line bMWL corresponding to the non-selected word line WL. It is assumed that the bank address BA and the signal VD have the same logic as each other. It is also assumed that the first voltage of the power terminal PS1 is H1, the second voltage of the power terminal PS2 is H2, and the third voltage of the power terminal PS3 is L.

### (Non-selected bank)

From t0 to t1, the bank address BA, that is, the signal VD is inactive at low level. In this case, the bank BK is non-selected. In the non-selected bank BK, since all the word lines WL are non-selected word lines, all the main word lines MWL and bMWL are main word lines MWL(WLnonsel) and bMWL(WLnonsel) respectively.

In the non-selected bank BK, the switching circuit SWC2 in FIG. 4 outputs the third voltage L (e.g., -1.5 V) of the power terminal PS3. The main word line MWL(WLnonsel) is therefore maintained at the third voltage L. Accordingly, in the non-selected bank BK, the word line WL is electrically disconnected from the word driving line WDRV.

Meanwhile, in the non-selected bank BK, the switching circuit SWC1 in FIG. 4 selectively outputs the second voltage H2 (e.g., 0.5 V) of the power terminal PS2. The switching circuit SWC3 receives the third voltage L from the switching circuit SWC2 and outputs a high-level side voltage of a reverse logic to the third voltage L, that is, the second voltage H2 from the switching circuit SWC1. The voltage of the main word line bMWL(WLnonsel) thus becomes the second voltage (e.g., 0.5 V) of the power terminal PS2. In this case, although the transistor bTRw is turned on, the channel resistance is relatively high. Accordingly, in the non-selected bank BK, the word line WL is connected to the word driving line VUX with electrically higher resistance than in a case of the first voltage H1. However, in the non-selected bank BK in the standby state, it is unnecessary to consider coupling noise. Further, since there is no non-selected word line WL sharing the word driving line WDRV with the selected word line WL in the non-selected bank BK, it is also unnecessary to consider current leakage from the word driving line WDRV. Accordingly, in the non-selected bank BK, there is no problem even if the word line WL is connected to the word driving line VUX with resistance that is high to some extent.

As described above, since the voltage of the main word line bMWL(WLnonsel) is maintained at the second voltage H2 of the power terminal PS2 in the standby state, the transistor bTRw is less likely to be affected by PBTI or the like and is less likely to deteriorate.

### (Selected bank)

At t1, when the bank address BA and the signal VD are activated to a high level, the bank BK enters the selected state. In the selected bank BK, the main word lines MWL and bMWL are divided into the main word lines MWL(WLsel) and bMWL(WLsel) corresponding to the selected word line WL and the main word lines MWL(WLnonsel) and bMWL(WLnonsel) corresponding to the non-selected word line WL.

The switching circuit SWC1 in FIG. 4 selectively outputs the first voltage H1 (e.g., 2 V) of the power terminal PS1.

From t1 to t2, all the word-line addresses WA are still inactive at low level. Therefore, the voltages of the main word lines MWL(WLsel) and MWL(WLnonsel) are still third voltage L. The voltages of the main word lines bMWL(WLsel) and bMWL(WLnonsel) become the first voltage H1 (e.g., 2 V) in accordance with the output of the switching circuit SWC1.

From t2 to t3, access by a read operation or a write operation is made to the bank BK.

At t2, when the word-line address WA is selectively activated, the switching circuit SWC2 corresponding to the selected word line WL outputs the first voltage H1 of the power terminal PS1. Accordingly, the switching circuit SWC2 selectively applies the first voltage H1 to the main word line MWL(WLsel). Further, the switching circuit SWC3 receives the first voltage H1 from the switching circuit SWC2 and outputs the third voltage L that is a low-level voltage of a reverse logic to the first voltage H1. The voltage of the main word line bMWL(WLsel) thus becomes the third voltage L. Accordingly, the selected word line WL is connected to the word driving line WDRV and electrically disconnected from the word driving line VUX. Consequently, the selected word line WL becomes a voltage according to the word driving line WDRV.

Meanwhile, the switching circuit SWC2 corresponding to the non-selected word line WL outputs the third voltage L of the power terminal PS3. The switching circuit SWC2 thereby selectively applies the third voltage L to the main word line MWL(WLnonsel). Further, the switching circuit SWC3 receives the third voltage L from the switching circuit SWC2 and outputs a high-level side voltage of a reverse logic to the third voltage L, that is, the first voltage H1 of the switching circuit SWC1. The voltage of the main word line bMWL(WLnonsel) consequently becomes the first voltage H1. Accordingly, the non-selected word line WL is connected to the word driving line VUX and electrically disconnected from the word driving line WDRV. Consequently, the non-selected word line WL becomes a voltage according to the word driving line VUX. At this time, the first voltage H1 being a high-level voltage is applied to the gate of the transistor bTRw between the non-selected word line WL and the word driving line VUX. However, a period in which a bank among the banks BK is accessed as a selected bank is very short and limited as compared with a period in which that bank is in the standby state. Therefore, the influence of PBTI on the transistor bTRw in the selected bank BK is relatively small.

At t3, when the read operation or the write operation ends, the word-line address WA is made inactive. Associated therewith, the switching circuit SWC2 corresponding to the selected word line WL outputs the third voltage L of the power terminal PS3. The switching circuit SWC2 accordingly applies the third voltage L to the main word line MWL(WLsel). Further, the switching circuit SWC3 receives the third voltage L from the switching circuit SWC2 and outputs the first voltage H1, which is a high-level voltage of a reverse logic to the third voltage L. Thus, the voltage of the main word line bMWL(WLsel) becomes the first voltage H1. Accordingly, the selected word line WL is electrically connected to the word driving line VUX and electrically disconnected from the word driving line WDRV. As a result, the selected word line WL becomes a voltage according to the word driving line VUX.

Meanwhile, the switching circuit SWC2 corresponding to the non-selected word line WL maintains the output of the third voltage L of the power terminal PS3. Thus, the switching circuit SWC2 selectively applies the third voltage L to the main word line MWL(WLnonsel). Further, the switching circuit SWC3 receives the third voltage L from the switching circuit SWC2 and maintains the output of the first voltage H1. Thus, the voltage of the main word line bMWL(WLnonsel) becomes the first voltage H1. Accordingly, the non-selected word line WL is connected to the word driving line VUX and electrically disconnected from the word driving line WDRV. The non-selected word line WL maintains a voltage according to the word driving line VUX. That is, from t3 to t4, both the main word lines MWL(WLsel) and MWL(WLnonsel) in the selected bank BK become the third voltage L. Both the main word lines bMWL(WLsel) and bMWL(WLnonsel) become the first voltage H1.

At t4, when the bank address BA and the signal VD are made inactive to low level, the bank BK enters the non-selected state. In the non-selected bank BK, all the main word lines MWL and bMWL are the main word lines MWL(WLnonsel) and bMWL(WLnonsel), as in the state from t0 to t1. The voltage of the main word line MWL(WLnonsel) is maintained at the third voltage L. The voltage of the main word line bMWL(WLnonsel) becomes the second voltage H2 (e.g., 0.5 V) of the power terminal PS2. Accordingly, in the standby state, the voltage of the main word line bMWL(WLnonsel) is maintained at the second voltage H2 of the power terminal PS2, and therefore the transistor bTRw is less likely to be affected by PBTI or the like and is less likely to deteriorate.

### (Second embodiment)

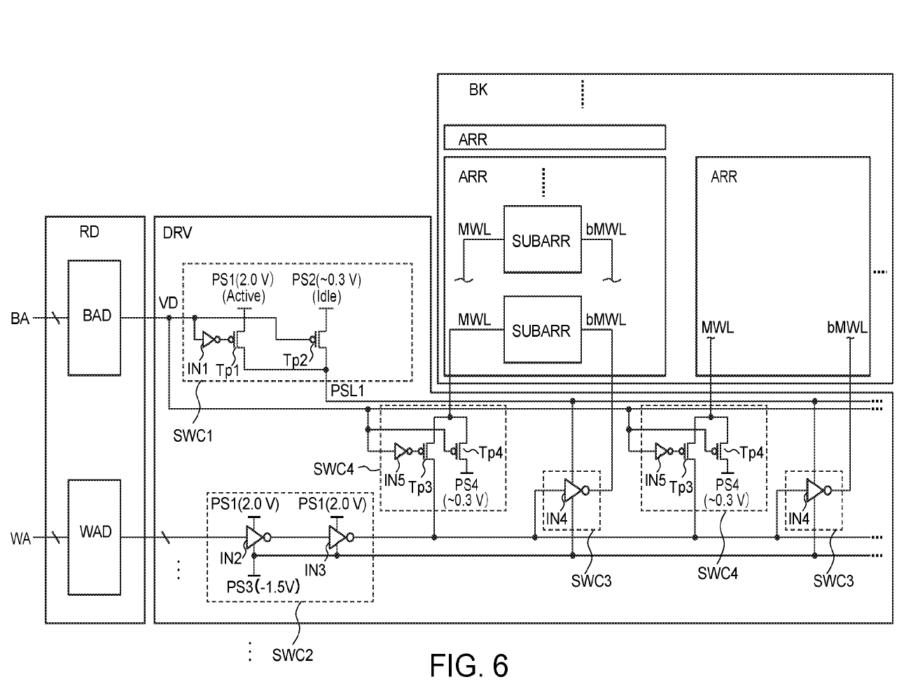

FIG. 6 is a block diagram illustrating a configuration example of a semiconductor storage device according to a second embodiment. In the second embodiment, the main word-line driver DRV further includes a plurality of switching circuits SWC4. The switching circuits SWC4 are provided between the main word lines MWL and the switching circuits SWC2, respectively. The switching circuits SWC4 are provided to correspond to the main word lines MWL, respectively.

Each switching circuit SWC4 includes a transistor Tp3, a transistor Tp4, and an inverter circuit IN5.

One of the source and the drain of the transistor Tp3 as a third switching element is connected to the output of the switching circuit SWC2, and the other is connected to the corresponding main word line MWL. The gate of the transistor Tp3 receives the first signal according to the bank address BA. The first signal is a signal obtained by inverting the signal VD corresponding to the bank address BA by the inverter circuit IN5, for example. The transistor Tp3 is a p-MOSFET, for example. When the bank address BA is at high level, for example, the transistor Tp3 is on and connects the output of the switching circuit SWC2 to the main word line MWL to supply the first voltage (e.g., 2 V) or the third voltage (e.g., -1.5 V) to the main word line MWL. The p-type transistor Tp3 and the inverter circuit IN5 may be replaced with an n-type transistor. By this replacement, the switching element SWC4 is configured by one CMOS and therefore the circuit configuration is simplified.

One of the source and the drain of the transistor Tp4 as a fourth switching element is connected to the power terminal PS4, and the other is connected to the main word line MWL. The gate of the transistor Tp4 receives the second signal according to the bank address BA. The second signal is a non-inverted signal of the signal VD corresponding to the bank address BA, for example. The transistor Tp4 is a p-MOSFET, for example. When the bank address BA is at low level, for example, the transistor Tp4 is on and connects the power terminal PS4 to the main word line MWL to supply a fourth voltage (e.g., 0.5 V) to the main word line MWL.

The inverter circuit IN5 is connected to the output of the bank address decoder BAD, and inverts the signal VD and outputs it.

The fourth voltage is lower than the first voltage (e.g., 2 V) of the power terminal PS1 and is higher than the third voltage (e.g., -1.5 V) of the power terminal PS3. The fourth voltage may be a voltage different from the second voltage (e.g., 0.3 V), for example, 0.5 V. However, it is preferable that the fourth voltage is equal to the second voltage (e.g., 0.3 V) of the power terminal PS2 in order to reduce the number of power terminals. The following description is provided assuming that the fourth voltage is equal to the second voltage and is, for example, 0.3 V.

For example, in the selected bank BK, in the switching circuit SWC4, the transistor Tp3 is on and connects the output of the switching circuit SWC2 to the main word line MWL. At this time, the transistor Tp4 is off.

Further, in the selected bank BK, the switching circuit SWC2 corresponding to the selected word line WL outputs the first voltage (e.g., 2 V) of the power terminal PS1 in accordance with the word-line address WA. Therefore, the switching circuit SWC4 connects the power terminal PS1 to the main word line MWL corresponding to the selected word line WL and applies the first voltage (e.g., 2 V) thereto.

Further, in the selected bank BK, the switching circuit SWC2 corresponding to the non-selected word line WL outputs the third voltage (e.g., -1.5 V) of the power terminal PS3 in accordance with the word-line address WA. Therefore, the switching circuit SWC4 connects the power terminal PS3 to the main word line MWL corresponding to the non-selected word line WL and applies the third voltage (e.g., -1.5 V) thereto.

Meanwhile, in the non-selected bank BK, in the switching circuit SWC4, the transistor Tp4 is turned on and connects the power terminal PS4 to the main word line MWL to apply the fourth voltage (e.g., 0.3 V) to the main word line MWL. At this time, the transistor Tp3 is off.

In the non-selected bank BK, all the word lines WL are non-selected. Therefore, the switching circuit SWC4 applies the fourth voltage (e.g., 0.3 V) of the power terminal PS4 to all the main word lines MWL in the non-selected bank BK.

As described above, the switching circuit SWC4 applies any of the power terminals PS1, PS3, and PS4 to each of the main word lines MWL based on the bank address BA and the word-line address WA.

Other configurations and functions of the second embodiment may be identical to those of the first embodiment.

Next, operations of the semiconductor storage device according to the second embodiment are described.

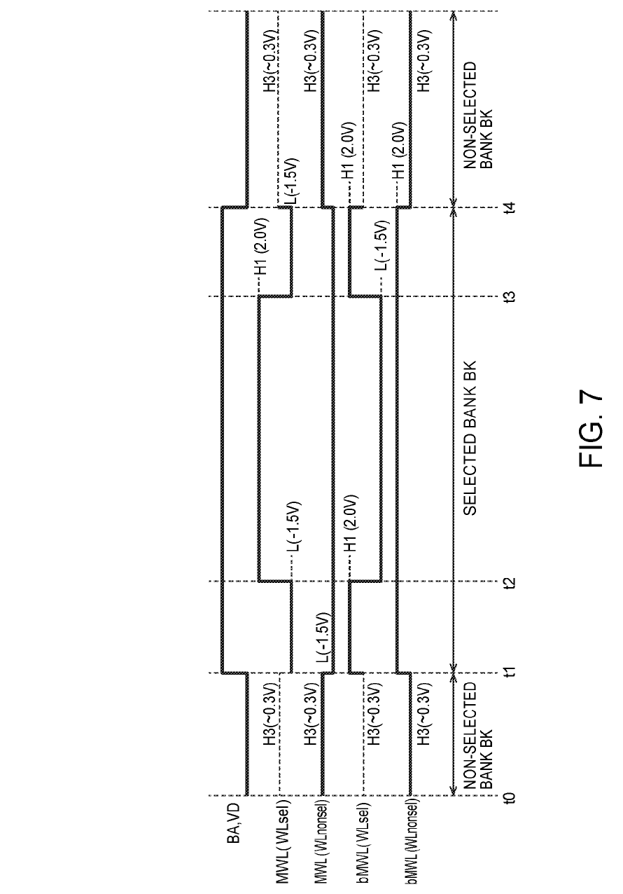

FIG. 7 is a timing chart illustrating an operation example of the semiconductor storage device according to the second embodiment. It is assumed that the first voltage of the power terminal PS1 is H1 (e.g., 2 V), the second and fourth voltages of the power terminals PS2 and PS4 are equal to each other and are H3 (e.g., 0.3 V), and the third voltage of the power terminal PS3 is L (e.g., -1.5 V). H3 may be lower than 0.3 V.

### (Non-selected bank)

From t0 to t1, the bank address BA, that is, the signal VD is inactive at low level. In this case, the bank BK is non-selected. In the non-selected bank BK, all the main word lines MWL and bMWL are the main word lines MWL(WLnonsel) and bMWL(WLnonsel).

In the non-selected bank BK, the switching circuit SWC4 in FIG. 6 outputs the fourth voltage H3 (e.g., 0.3 V) of the power terminal PS4. The main word line MWL(WLnonsel) is thus maintained at the fourth voltage H3. In this case, although the transistor TRw is turned on, the channel resistance is relatively high. Accordingly, in the non-selected bank BK, the word line WL is electrically connected to the word driving line WDRV with higher resistance than in a case of the first voltage H1. However, since the word line WL is not driven at high speed in the non-selected bank BK in the standby state, the voltage of the word line WL can be maintained at the word driving line WDRV (e.g., -1 V).

Accordingly, in the non-selected bank BK, the word line WL is electrically connected to the word driving line WDRV, although the resistance is high.

Meanwhile, the switching circuit SWC1 in FIG. 6 selectively outputs the second voltage H2 (e.g., 0.3 V) of the power terminal PS2. Further, in the non-selected bank BK, since all the word-line addresses WA are inactive at low level, the switching circuit SWC2 outputs the third voltage L (e.g., -1.5 V) of the power terminal PS3. Therefore, the switching circuit SWC3 receives the third voltage L from the switching circuit SWC2 and outputs a high-level side voltage of a reverse logic to the third voltage L, that is, the second voltage H2 from the switching circuit SWC1. The voltage of the main word line bMWL(WLnonsel) thus becomes the second voltage H2 (e.g., 0.3 V) of the power terminal PS2. In this case, although the transistor bTRw is turned on, the channel resistance is relatively high. Accordingly, in the non-selected bank BK, the word line WL is electrically connected to the word driving line VUX with higher resistance than in a case of the first voltage H1. However, since the word line WL is not driven at high speed in the non-selected bank BK in the standby state, the voltage of the word line WL can be maintained at the word driving line VUX (e.g., -1 V).

As described above, both the voltages of the main word lines MWL(WLnonsel) and bMWL(WLnonsel) are maintained at the second or fourth voltage H2 or H3 (both H2 and H3 are 0.3 V, for example) of the power terminal PS2 or PS4, respectively, in the standby state. In the second embodiment, both the word driving lines VUX and WDRV maintained at a low-level voltage (e.g., -1 V) in the standby state apply the low-level voltage (e.g., -1 V) to the word lines WL via the transistors TRw and bTRw which are respectively connected to the main word lines MWL and bMWL biased by the second and fourth voltages H2 and H3. As a result, in the second embodiment, the second and fourth voltages H2 and H3 can be made lower than the second voltage H2 (e.g., 0.5 V) in the first embodiment. Thus, the influence of PBTI or the like on the transistor bTRw can be further reduced, so that deterioration of the transistor bTRw can be further reduced.

Other operations in the non-selected bank BK according to the second embodiment are identical to those in the non-selected bank BK of the first embodiment.

### (Selected bank)

At t1, when the bank address BA and the signal VD are activated to high level, the bank BK enters the selected state. Regarding an operation in the selected bank BK, the main word lines MWL and bMWL are divided into the main word lines MWL(WLsel) and bMWL(WLsel) corresponding to the selected word line WL and the main word lines MWL(WLnonsel) and bMWL(WLnonsel) corresponding to the non-selected word line WL.

The switching circuit SWC1 in FIG. 6 selectively outputs the first voltage H1 (e.g., 2 V) of the power terminal PS1.

From t1 to t2, all the word-line addresses WA are still inactive at low level. Therefore, the voltages of the main word lines MWL(WLsel) and MWL(WLnonsel) are still third voltage L. The voltages of the main word lines bMWL(WLsel) and bMWL(WLnonsel) become the first voltage H1 (e.g., 2 V) in accordance with the output of the switching circuit SWC1.

From t2 to t3, access by a read operation or a write operation is made to the bank BK.

At t2, when the word-line address WA is selectively activated, the switching circuit SWC2 corresponding to the selected word line WL outputs the first voltage H1 of the power terminal PS1. Accordingly, the switching circuit SWC2 selectively applies the first voltage H1 to the switching circuit SWC4.

In the switching circuit SWC4, the inverter circuit IN5 receives the bank address BA and outputs a low-level voltage of a reverse logic to the signal VD. The transistor Tp3 is thus turned on and applies the first voltage H1 from the switching circuit SWC2 to the main word line MWL(WLsel) corresponding to the selected word line WL. Further, the transistor Tp4 is turned off by receiving the bank address BA. Accordingly, the voltage of the main word line MWL(WLsel) becomes the first voltage H1.

The switching circuit SWC3 receives the first voltage H1 from the switching circuit SWC2 and outputs the third voltage L that is a low-level voltage of a reverse logic to the first voltage H1. Thus, the voltage of the main word line bMWL(WLsel) becomes the third voltage L. Accordingly, the selected word line WL is electrically connected to the word driving line WDRV and electrically disconnected from the word driving line VUX. Consequently, the selected word line WL becomes a voltage according to the word driving line WDRV.

Meanwhile, the switching circuit SWC2 corresponding to the non-selected word line WL outputs the third voltage L of the power terminal PS3. Accordingly, the switching circuit SWC2 selectively applies the third voltage L to the switching circuit SWC4.

In the switching circuit SWC4, the inverter circuit IN5 receives the bank address BA and outputs a low-level voltage of a reverse logic to the signal VD. Consequently, the transistor Tp3 is turned on and applies the third voltage L from the switching circuit SWC2 to the main word line MWL(WLnonsel) corresponding to the non-selected word line WL. Further, the transistor Tp4 is turned off by receiving the bank address BA. Accordingly, the voltage of the main word line MWL(WLnonsel) becomes the third voltage L.

The switching circuit SWC3 receives the third voltage L from the switching circuit SWC2 and outputs a high-level side voltage of a reverse logic to the third voltage L, that is, the first voltage H1 of the switching circuit SWC1. The voltage of the main word line bMWL(WLnonsel) thus becomes the first voltage H1. Accordingly, the non-selected word line WL is connected to the word driving line VUX and electrically disconnected from the word driving line WDRV. Consequently, the non-selected word line WL becomes a voltage according to the word driving line VUX. At this time, the first voltage H1 being a high-level voltage is applied to the gate of the transistor bTRw between the non-selected word line WL and the word driving line VUX. As a result, the voltage states of the main word lines MWL and bMWL in the selected bank BK according to the second embodiment become the same as those in the selected bank BK according to the first embodiment.

At t3, when the read operation or the write operation ends, the word-line address WA is made inactive. Associated therewith, the switching circuit SWC2 corresponding to the selected word line WL outputs the third voltage L of the power terminal PS3. Thus, the switching circuit SWC4 applies the third voltage L to the main word line MWL(WLsel) corresponding to the selected word line WL. The switching circuit SWC3 receives the third voltage L from the switching circuit SWC2 and outputs the first voltage H1 that is a high-level voltage of a reverse logic to the third voltage L. Therefore, the voltage of the main word line bMWL(WLsel) becomes the first voltage H1. Accordingly, the selected word line WL is electrically connected to the word driving line VUX and electrically disconnected from the word driving line WDRV. Consequently, the selected word line WL becomes a voltage according to the word driving line VUX.

Meanwhile, the switching circuit SWC2 corresponding to the non-selected word line WL maintains the output of the third voltage L of the power terminal PS3. Accordingly, the switching circuit SWC4 still applies the third voltage L from the switching circuit SWC2 to the main word line MWL(WLnonsel). Further, the switching circuit SWC3 receives the third voltage L from the switching circuit SWC2 and maintains the output of the first voltage H1. Thus, the voltage of the main word line bMWL(WLnonsel) becomes the first voltage H1. Accordingly, the non-selected word line WL is connected to the word driving line VUX, is electrically disconnected from the word driving line WDRV, and maintains a voltage according to the word driving line VUX. That is, from t3 to t4, all the main word lines MWL(WLsel) and MWL(WLnonsel) in the selected bank BK become the third voltage L. All the main word lines bMWL(WLsel) and bMWL(WLnonsel) become the first voltage H1.

At t4, when the bank address BA and the signal VD are made inactive to low level, the bank BK enters the non-selected state. In the non-selected bank BK, all the main word lines MWL and bMWL are the main word lines MWL(WLnonsel) and bMWL(WLnonsel), as in the state from t0 to t1. The voltages of the main word line MWL(WLnonsel) and bMWL(WLnonsel) are respectively maintained at the fourth and second voltages H3 and H2 (both H3 and H2 are 0.3 V, for example).

As described above, both the voltages of the main word lines MWL(WLnonsel) and bMWL(WLnonsel) are maintained at the second or fourth voltage H2 or H3 (both H2 and H3 are 0.3 V, for example) of the power terminal PS2 or PS4, respectively, in the standby state, respectively. In the second embodiment, both the word driving lines WDRV and VUX maintained at a low-level voltage (e.g., -1 V) in the standby state apply the low-level voltage (e.g., -1 V) to the word lines WL via the transistors TRw and bTRw which are respectively connected to the main word lines MWL and bMWL biased by the second and fourth voltages H2 and H3. As a result, in the second embodiment, the second and fourth voltages H2 and H3 can be made lower than the second voltage H2 (e.g., 0.5 V) in the first embodiment. Thus, the influence of PBTI or the like on the transistor bTRw can be further reduced, so that deterioration of the transistor bTRw can be further reduced.

Other operations of the second embodiment are the same as those of the first embodiment. Accordingly, the second embodiment can attain identical effects as those of the first embodiment.

### (Modifications)

It suffices that transistors constituting the cell transistor CT, the transistors TRw, bTRw, TRb, Tp1 to Tp4, and the inverter circuits IN1 to IN5 are MOSFETs using oxide semiconductor at least in channel regions.

The above transistors are formed by using oxide semiconductor. The channel material of the cell transistor CT is constituted of an oxide semiconductor material containing an n-type or p-type material system, for example. The channel material may contain indium, gallium, zinc, and oxygen (for example, in the form of indium gallium zinc oxide (IGZO)) entirely or partly, for example, and such a channel material may have the n-type conductivity. For example, the channel material can contain tin and oxygen (for example, in the form of tin oxide), antimony and oxygen (for example, in the form of antimony oxide), indium and oxygen (for example, in the form of indium oxide), indium, tin, and oxygen (for example, in the form of indium tin oxide), titanium and oxygen (for example, in the form of titanium oxide), zinc and oxygen (for example, zinc oxide), indium, zinc, and oxygen (for example, in the form of indium zinc oxide), gallium and oxygen (for example, in the form of gallium oxide), titanium, oxygen, and nitrogen (for example, in the form of titanium oxynitride), ruthenium and oxygen (for example, in the form of ruthenium oxide), or tungsten and oxygen (for example, in the form of tungsten oxide).

The material for the channel region of the above transistor is preferably crystalline oxide semiconductor, for example, but may be amorphous oxide semiconductor. Specific examples of oxide semiconductor include zinc tin oxide (ZTO), IGZO (also called gallium indium zinc oxide (GIZO)), indium zinc oxide (IZO), ZnOx, InOx, In2O3, SnO2, TiOx, ZnxOyNz, MgxZnyOz, InxZnyOz, InxGayZnzOa, ZrxInyZnzOa, HfxInyZnzOa, SnxInyZnzOa, AlxSnyInzZnaOd, SixInyZnaOa, ZnxSnyOz, AlxZnySnzOa, GaxZnySnzOa, ZrxZnySnzOa, InGaxSiyOz, and other similar materials.

Accordingly, the semiconductor storage device according to the present embodiment can achieve low power consumption.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a memory portion including a plurality of banks respectively including a plurality of memory cells, the banks being selectively accessed in a read operation or a write operation;
a plurality of first wires respectively connected to the memory cells arranged in a first direction in common in the memory portion;
a plurality of second wires respectively connected to the memory cells arranged in a second direction crossing the first direction in common in the memory portion;
a plurality of third wires respectively provided for the second wires arranged in a third direction crossing the first and second directions in common;
a plurality of first driving lines respectively connected to the first wires arranged in the third direction in common;
a plurality of first transistors in each of which one of a source and a drain is connected to corresponding one of the first wires, and another is connected to corresponding one of the first driving lines;
a plurality of fourth wires respectively connected to gates of the first transistors arranged in the second direction in common;
a plurality of second driving lines respectively provided for the first wires arranged in the second direction in common;
a plurality of second transistors in each of which one of a source and a drain is connected to corresponding one of the first wires and another is connected to corresponding one of the second driving lines;
a plurality of fifth wires respectively connected to gates of the second transistors arranged in the second direction in common; and
a driver circuit configured to drive voltages of the fourth and fifth wires, wherein
the driver circuit applies a first voltage to one of the fifth wires corresponding to non-selected one of the first wires in a first bank selected in the banks and applies a second voltage having an absolute value smaller than an absolute value of the first voltage to the fifth wires in a second bank that is non-selected.

2. The device of claim 1, further comprising:
a first power terminal configured to supply the first voltage;
a second power terminal configured to supply the second voltage; and
a third power terminal configured to supply a third voltage to be applied to one of the fifth wires corresponding to one of the first wires selected as a target of reading or writing in the first bank, wherein
the second voltage is higher than the third voltage.

3. The device of claim 2, wherein the driver circuit
applies the first voltage to one of the fourth wires corresponding to the one of the first wires selected in the first bank, and
applies the third voltage to the fourth wires in the second bank.

4. The device of claim 2, wherein the driver circuit further includes a plurality of first switching circuits provided to correspond to the banks, respectively, and respectively configured to connect either one of the first and second power terminals to corresponding one of the fifth wires based on a first address selecting the first bank.

5. The device of claim 4, wherein the first switching circuits respectively include
a first switching element in which one of a source and a drain is connected to the first power terminal, another is connected to any of the fifth wires, and a gate receives a first signal according to the first address, and
a second switching element in which one of a source and a drain is connected to the second power terminal, another is connected to any of the fifth wires, and a gate receives a second signal of a reverse logic to the first signal.

6. The device of claim 5, wherein
the first switching element connects the first power terminal to one of the fifth wires corresponding to non-selected one of the first wires in the first bank, and
the second switching element connects the second power terminal to the fifth wires in the second bank.

7. The device of claim 2, wherein the driver circuit further includes a plurality of second switching circuits provided to correspond to the fourth wires, respectively and respectively configured to connect any of the first and third power terminals to each of the fourth wires based on a second address selecting one of the first wires as the target of reading or writing in the first bank.

8. The device of claim 7, wherein the second switching circuits respectively include a first inverter circuit connected to the first and third power terminals and configured to apply the first voltage to one of the fourth wires corresponding to one of the first wires selected in the first bank based on the second address and apply the third voltage to one of the fourth wires corresponding to non-selected one of the first wires in the first bank.

9. The device of claim 4, wherein the driver circuit further includes a plurality of third switching circuits provided to correspond to the fifth wires, respectively and respectively configured to apply either one of a voltage of the first or second power terminal from the first switching circuit and a voltage of the third power terminal to each of the fifth wires based on a second address selecting one of the first wires as the target of reading or writing in the first bank.

10. The device of claim 2, wherein the driver circuit applies a fourth voltage lower than the first voltage and higher than the third voltage to the fourth wires in the second bank.

11. The device of claim 10, wherein the fourth voltage is equal to the second voltage.

12. The device of claim 10, wherein the driver circuit further includes
a fourth power terminal configured to supply the fourth voltage,
a plurality of second switching circuits provided to correspond to the fourth wires, respectively, and respectively configured to connect either one of the first and third power terminals to each of the fourth wires based on a second address selecting one of the first wires as the target of reading or writing in the first bank, and
a plurality of fourth switching circuits provided between the fourth wires and the second switching circuits, respectively, and respectively configured to connect either one of the first or third power terminal and the fourth power terminal to each of the fourth wires based on a first address selecting the first bank.

13. The device of claim 12, wherein the fourth switching circuits respectively include
a third switching element in which one of a source and a drain is connected to the first or third power terminal via corresponding one of the second switching circuits, another is connected to any of the fourth wires, and a gate receives a first signal according to the first address, and
a fourth switching element in which one of a source and a drain is connected to the fourth power terminal, another is connected to any of the fourth wires, and a gate receives a second signal of a reverse logic to the first signal.

14. The device of claim 1, wherein each of the memory cells includes
at least one cell transistor in which one of a source and a drain is connected to any of the second wires and a gate is connected to any of the first wires, and
at least one cell capacitor connected at one end to another of the source and the drain of the cell transistor.

15. The device of claim 14, wherein the cell transistor contains oxide semiconductor in a channel region.

16. A method of controlling a semiconductor storage device including: a memory portion including a plurality of banks each of which includes a plurality of memory cells and that are selectively accessed in a read operation or a write operation; a plurality of first wires respectively connected to the memory cells arranged in a first direction in common in the memory portion; a plurality of second wires respectively connected to the memory cells arranged in a second direction crossing the first direction in common in the memory portion; a plurality of third wires respectively provided for the second wires arranged in a third direction crossing the first and second directions in common; a plurality of first driving lines respectively provided for the first wires arranged in the third direction in common; a plurality of first transistors in each of which one of a source and a drain is connected to corresponding one of the first wires, and another is connected to corresponding one of the first driving lines; a plurality of fourth wires respectively connected to gates of the first transistors arranged in the second direction in common; a plurality of second driving lines respectively provided for the first wires arranged in the second direction in common; a plurality of second transistors in each of which one of a source and a drain is connected to corresponding one of the first wires and another is connected to corresponding one of the second driving lines; a plurality of fifth wires respectively connected to gates of the second transistors arranged in the second direction in common; and a driver circuit configured to drive voltages of the fourth and fifth wires, the method comprising:
applying a first voltage to one of the fifth wires corresponding to non-selected one of the first wires in a first bank selected in the banks; and
applying a second voltage having an absolute value smaller than an absolute value of the first voltage to the fifth wires in a second bank that is non-selected.

17. The method of claim 16, wherein the semiconductor storage device further includes a first power terminal configured to supply the first voltage, a second power terminal configured to supply the second voltage, and a third power terminal configured to supply a third voltage to one of the fifth wires corresponding to one of the first wires selected as a target of reading or writing in the first bank,
the second voltage is higher than the third voltage, and
the method further comprises:
applying the first voltage to one of the fourth wires corresponding to one of the first wires selected in the first bank; and
applying the third voltage to the fourth wires in the second bank.

18. The method of claim 17, wherein
applying the first voltage to one of the fifth wires comprises connecting the first power terminal to one of the fifth wires corresponding to non-selected one of the first wires in the first bank based on a first address selecting the first bank, and
applying the second voltage comprises connecting the second power terminal to the fifth wires in the second bank.
